(19) United States
(12) Patent Application Publication
(10) Pub. No.: US 2008/0224900 A1
(43) Pub. Date: Sep. 18, 2008

(54) CAPACITIVE SWITCH

(76) Inventors: Yuji Konno, Fukushima-ken (JP); Yoshihisa Endo, Fukushima-ken (JP)

Correspondence Address: BRINKS HOFER GILSON & LIONE, P.O. BOX 10395, CHICAGO, IL, 60610, US

(21) Appl. No.: 12/047,526

(22) Filed: Mar. 13, 2008

(30) Foreign Application Priority Data
Mar. 14, 2007 (JP) 2007-065663

(51) Int. Cl. H03K 17/94

(52) U.S. Cl. 341/33

(57) ABSTRACT

An input key and a detection circuit are not directly connected but are connected via a first capacitor. This prevents electrostatic noise obtained by the input key from directly entering the detection circuit, thereby protecting the detection circuit. Further, a first coupling line adapted to establish a connection between the input key and one of a pair of counter electrodes and a second coupling line adapted to establish a connection between the other counter electrode and the detection circuit are surrounded by ground electrodes. Thus, the effect of electrostatic noise is suppressed to provide a stable operation of the capacitive switch.

### CLAIM OF PRIORITY

This application claims benefit of the Japanese Patent Application No. 2007-065663 filed on Mar. 14, 2007, which is hereby incorporated in its entirety by reference.

### BACKGROUND OF THE INVENTION

1. Field of the Invention

The present invention relates to capacitive switches mountable in various types of electronic equipment, and more specifically to a capacitive switch with an electrostatic noise countermeasure.

2. Description of the Related Art

Japanese Unexamined Patent Application Publication No. 7-73790 (FIGS. 8 to 10) describes an invention relating to a switch device including a touch panel for detecting a capacitance, the touch panel being disposed on a front panel of an automatic vending machine.

When a part of a human body approaches or comes in contact with the touch panel, a capacitance formed between the touch panel and the human body changes. In the switch device, a phase delay generated between signals due to such a change in the capacitance is detected by an internal circuit, and switching capabilities are provided.

In the switch device, the touch panel is composed of electrically conductive resin or electrically conductive metal, and is directly connected to the internal circuit. The touch panel is disposed on the front panel so as to be exposed.

This may allow electrostatic noise to enter through the touch panel. If the electrostatic noise is directly transmitted to the internal circuit, problems such as malfunctioning of the switching operation and destruction of the internal circuit occur.

There arises another problem with the above switch device. The switch device has two structures in which a capacitance generated by the touch of a part of a human body and a capacitance generated by the touch of a gloved finger are detected, both of which are variable. Therefore, it is difficult to secure a stable capacitance, and the detection accuracy is likely to be low. This problem may be addressable by providing a commercially available capacitor as a fixed capacitor between the touch panel and the circuit. This approach, however, may increase the number of parts, and it is difficult to reduce manufacturing cost.

### SUMMARY

A capacitive switch is disclosed for performing a switch opening and closing operation depending on whether or not a human body approaches or comes in contact with the capacitive switch on the basis of a change in capacitance which is monitored. The capacitive switch includes an electrically conductive input key provided so as to be exposed on a surface of the capacitive switch; a first capacitor having an end connected to the input key; and a detection circuit configured to apply a predetermined signal to the first capacitor and to detect an output of the first capacitor to output a switching signal corresponding to the detected output. The first capacitor is formed by a base member and a pair of counter electrodes arranged on either side of the base member so as to face each other with the base member therebetween.

The input key and the detection circuit are not directly connected but are connected via the first capacitor. With this configuration, electrostatic noise obtained by the input key is prevented from directly entering the detection circuit, and the detection circuit can be protected.

### BRIEF DESCRIPTION OF THE DRAWINGS

FIG. 1 is a front view of a monitor equipped with a capacitive switch according to an embodiment

FIG. 2 is a partial perspective view of the monitor shown in FIG. 1;

FIG. 3 is a cross-sectional view taken along a line III-III shown in FIG. 2;

FIG. 4A is a plan view of a front side of a substrate;

FIG. 4B is a rear view of a back side of the substrate;

FIG. 5 is a conceptual diagram equivalently showing electromagnetic shielding in the capacitive switch;

FIG. 6 is a schematic circuit diagram showing an example of a detection circuit;

FIG. 7A is a diagram showing a relationship between input and output signals of an AND circuit at a switch non-operation time; and

FIG. 7B is a diagram showing a relationship between input and output signals of the AND circuit at a switch operation time.

### DESCRIPTION OF THE EMBODIMENTS

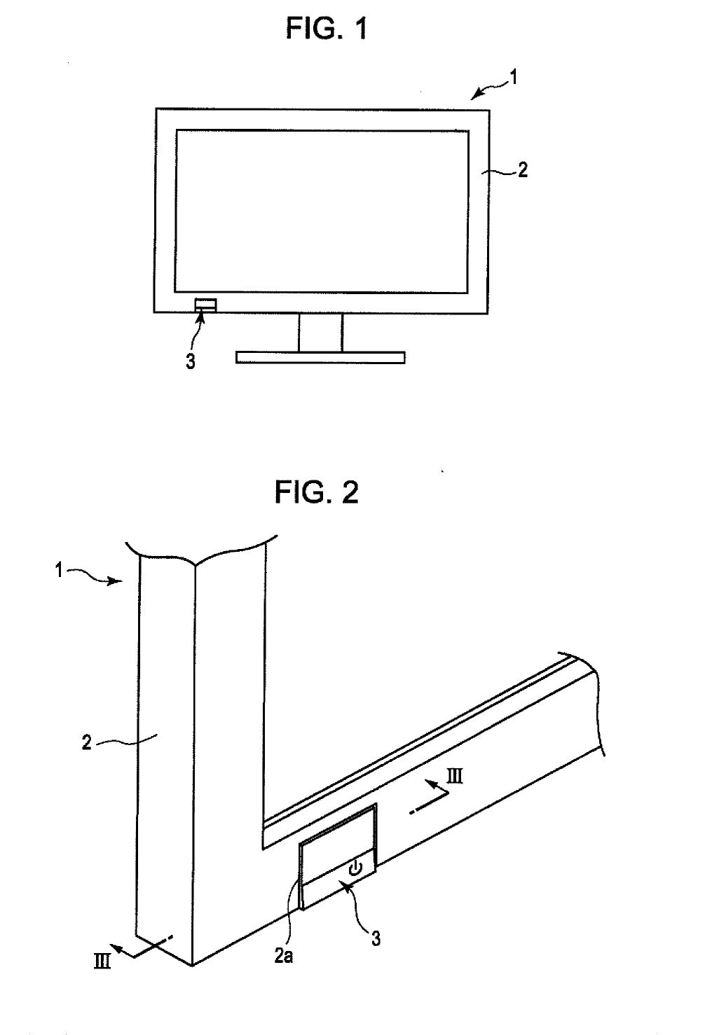

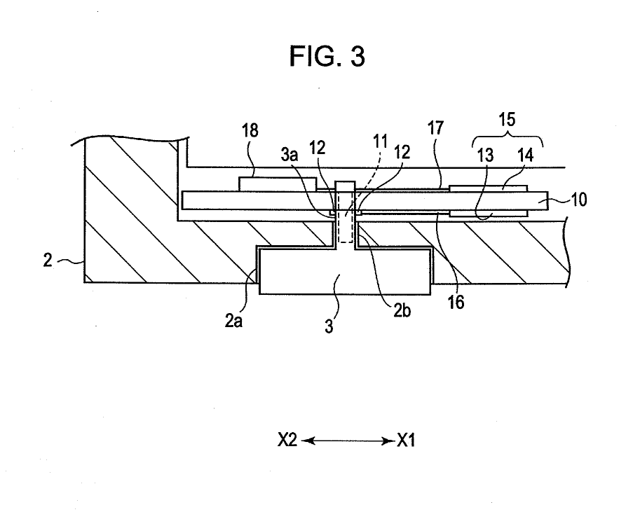

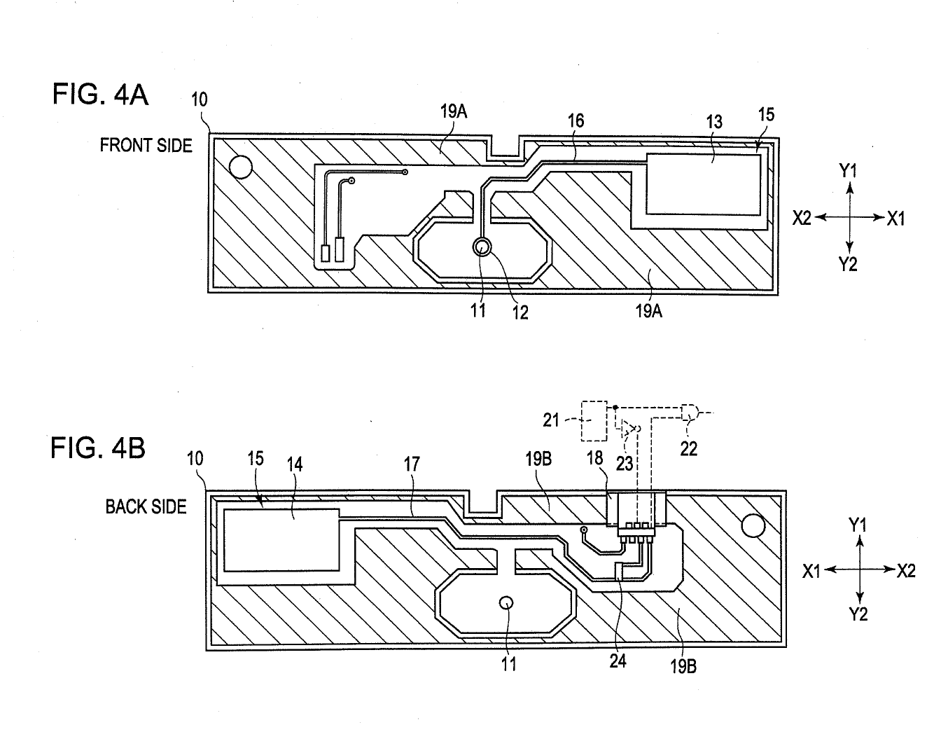

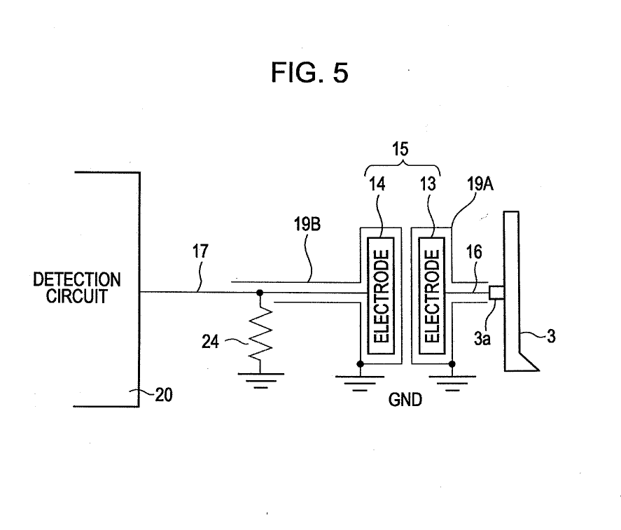

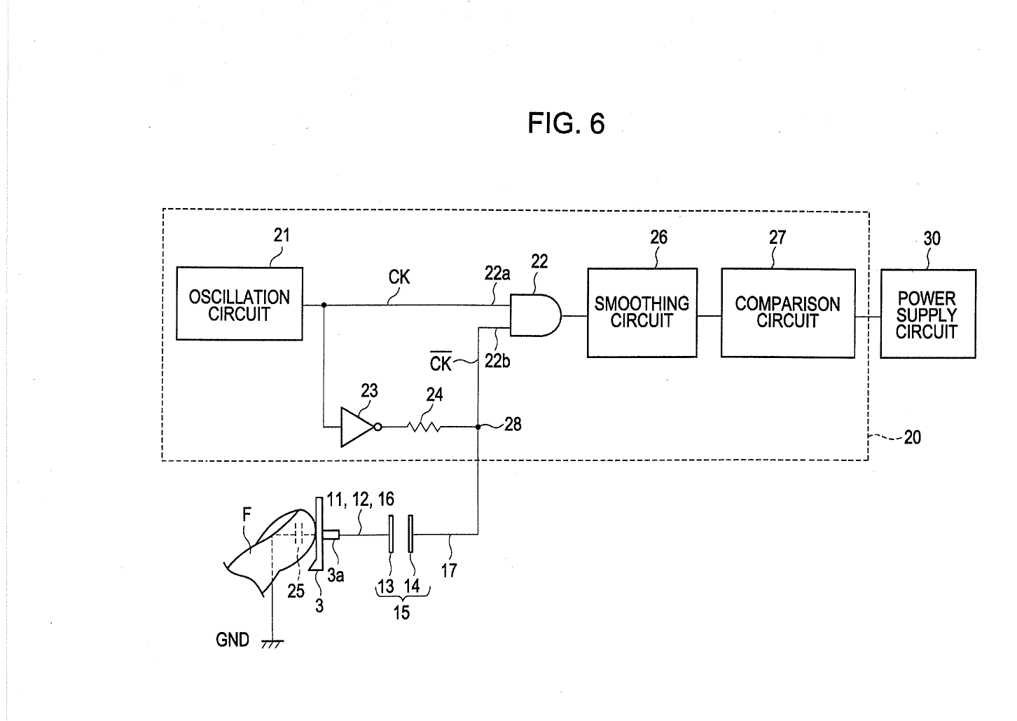

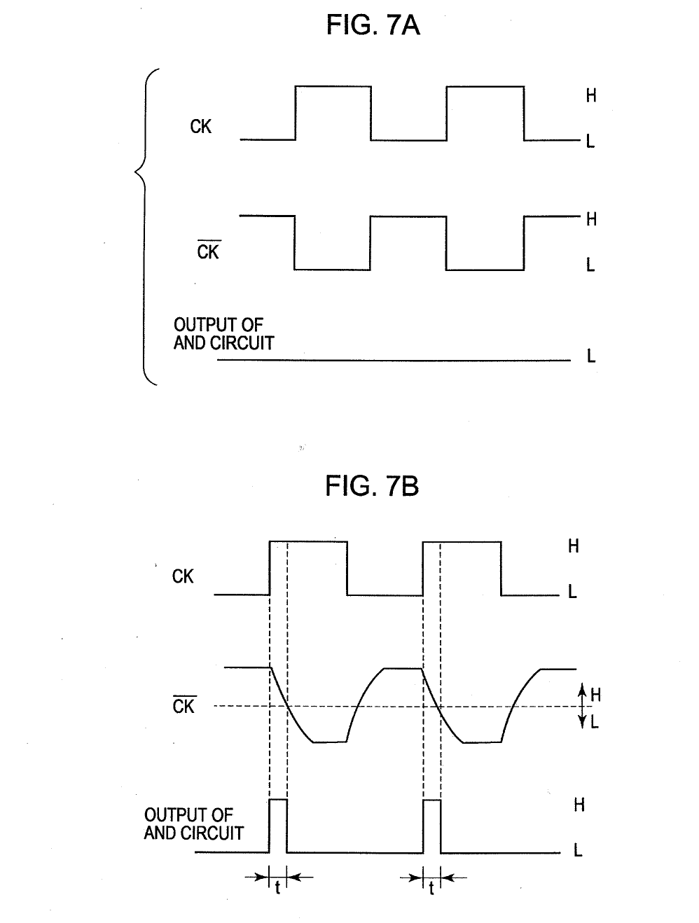

FIG. 1 is a front view of a monitor equipped with a capacitive switch according to an embodiment. FIG. 2 is a partial perspective view of the monitor shown in FIG. 1, and FIG. 3 is a cross-sectional view taken along a line III-III shown in FIG. 2. FIG. 4A is a plan view of a front side of a substrate, and FIG. 4B is a rear view of a back side of the substrate. FIG. 5 is a conceptual diagram equivalently showing electromagnetic shielding in the capacitive switch, and FIG. 6 is a schematic circuit diagram showing an example of a detection circuit. FIG. 7A shows a relationship between input and output signals of an AND circuit at a switch non-operation time, and FIG. 7B shows a relationship between input and output signals of the AND circuit at a switch operation time.

As shown in FIGS. 1 and 2, the capacitive switch of the present invention is used as, for example, but not limited to, a switch for powering on or off a monitor 1.

The monitor 1 shown in FIG. 1 may be a television or computer flat-screen display. The monitor 1 has a frame-shaped housing 2. A liquid crystal display, a plasma display, or the like is housed in the housing 2.

The housing 2 has a recessed portion 2a in a front surface thereof. An input key 3 is mounted in the recessed portion 2a so that a surface of the input key 3 is exposed. Power on-off symbol is printed on the surface of the input key 3 to indicate that the input key 3 is a power switch. A connection protrusion 3a is integrally formed with a rear hidden surface of the input key 3 so as to extend toward the inside of the housing 2. The connection protrusion 3a is formed into a cylindrical shape, and is inserted into a through-hole 2b formed in the recessed portion 2a. A leading end of the connection protrusion 3a passes through the through-hole 2b and reaches the inside of the housing 2.

In this embodiment, the input key 3 is made of a base material composed of an insulating resin material, and a surface of the base material is coated with an electrically conductive resin material. The input key 3 includes at least an electrically conductive surface. Thus, the input key 3 may be made of an electrically conductive metal material or an electrically conductive resin. However, the input key 3 of this embodiment may be more lightweight and inexpensive than an input key made of a metal material or an electrically conductive material.

As shown in FIG. 3, a substrate (base member) 10 is provided in the inside of the housing 2 so as to face the input key 3. The substrate 10 is made of an insulating or dielectric material. As shown in FIGS. 4A and 4B, the substrate 10 has a predetermined electrically conductive pattern formed on each of the front and back sides thereof. The predetermined electrically conductive patterns may be formed by, for example, etching a thin electrically conductive film formed of copper foil or the like laminated on the front and back sides of the substrate 10.

An internal pin (connection portion) 11 associated with the connection protrusion 3a is provided substantially at a center of the substrate 10. The internal pin 11 is made of an electrically conductive material, and has an outer dimension which is the same as or slightly smaller than an inner dimension of the cylindrical connection protrusion 3a. The internal pin 11 is inserted in the cylindrical connection protrusion 3a. On the substrate 10, an electrically conductive circular pattern (connection portion) 12 is formed around the proximal part of the internal pin 11. The internal pin 11 and the circular pattern 12 are electrically connected by means of, for example, soldering.

On the front side of the substrate 10, a first counter electrode 13 is formed on the X1 side as viewed in FIG. 4A. On the back side of the substrate 10, a second counter electrode 14 having substantially the same area as the first counter electrode 13 is formed on the X1 side as viewed in FIG. 4B at a position facing the first counter electrode 13. The first and second counter electrodes 13 and 14 face each other with the substrate 10 therebetween, and form a first capacitor 15 (with a capacitance C1). The capacitance C1 is given by C1=∈·S/d (expressed in farads (F)), where S denotes the area of a portion where the first and second counter electrodes 13 and 14 forming the first capacitor 15 face each other, d denotes the distance between the first and second counter electrodes 13 and 14 in the thickness direction, and 6 denotes the dielectric constant specific to the material of the substrate 10. The capacitance C1 of the first capacitor 15 is several picofarads (pF). The capacitance C1 of the first capacitor 15 does not largely vary due to ambient environmental changes, and the first capacitor 15 functions as a stable fixed capacitor.

As shown in FIG. 4A, on the front side of the substrate 10, the circular pattern 12 and the first counter electrode 13 are connected via a first coupling line 16. The first coupling line 16 forms a portion of the electrically conductive pattern.

As shown in FIG. 4B, a connector 18 is provided on the back side of the substrate 10. The second counter electrode 14 and the connector 18 are connected via a second coupling line 17. The second coupling line 17 forms a portion of the electrically conductive pattern. A power supply unit (not shown) including a detection circuit 20 described below is provided outside the substrate 10, and the connector 18 and the detection circuit 20 are connected via a connection cable (not shown).

On the front side of the substrate 10, the input key 3 and the first counter electrode 13 forming the first capacitor 15 are connected via the connection protrusion 3a, the internal pin 11, the circular pattern 12, and the first coupling line 16. On the back side of the substrate 10, the second counter electrode 14 forming the first capacitor 15 and the detection circuit 20 provided outside the substrate 10 are connected via the second coupling line 17 and the connection cable (not shown). In other words, the input key 3 and the detection circuit 20 are not directly connected but are connected via the first capacitor 15. With this configuration, electrostatic noise (in particular, an impulse voltage surge) obtained by the input key 3 is prevented from directly entering the detection circuit 20, and the detection circuit 20 can therefore be protected.

As indicated by shaded areas in FIGS. 4A and 4B, ground electrodes 19A and 19B are formed on the front and back sides of the substrate 10, respectively. On the front side of the substrate 10, the first counter electrode 13 is located at a position slightly distant from the circular pattern 12. The ground electrode 19A is arranged so as to sandwich the first coupling line 16 in the Y direction along the first coupling line 16 extending in the X direction. On the back side of the substrate 10, the connector 18 is provided at a position slightly distant from the second counter electrode 14. The ground electrode 19B is arranged so as to sandwich second coupling line 17 in the Y direction along the second coupling line 17 extending in the X direction. The ground electrodes 19A and 19B are connected to a ground GND.

The ground electrode 19A is formed so as to surround the internal pin 11 and the circular pattern (connection portion) 12. The ground electrode 19B is formed so as to surround the internal pin 11.

As shown in FIG. 5, the first counter electrode 13, the first coupling line 16, the internal pin 11, and the circular pattern (connection portion) 12 are surrounded by the ground electrode 19A on the front side of the substrate 10, and are substantially electromagnetically shielded. Likewise, the second counter electrode 14 and the second coupling line 17 are surrounded by the ground electrode 19B on the back side of the substrate 10, and are substantially electromagnetically shielded. Thus, electrostatic noise superimposed on the input key 3 could be prevented from affecting the detection circuit 20 over the ground electrode 19A or 19B. The effect of electrostatic noise transmitted from the first counter electrode 13 to the second counter electrode 14 could also be prevented.

Next, a circuit structure and operation of the capacitive switch will be described.

As shown in the circuit diagram shown in FIG. 6, the capacitive switch of the present invention includes an oscillation circuit 21 that outputs a clock signal having periodic cycles. An AND circuit 22 is provided after the oscillation circuit 21. A clock signal CK which is output from the oscillation circuit 21 is directly input to a first input terminal 22a of the AND circuit 22, and an inversion signal CK-bar is input to a second input terminal 22b of the AND circuit 22 via an inverter 23 and a fixed resistor 24 (with a resistance R).

The second coupling line 17 extending from the second counter electrode 14 is connected to a node 28 between an end of the fixed resistor 24 and the second input terminal 22b of the AND circuit 22. The first counter electrode 13 is connected to the input key 3. For example, a smoothing circuit 26 adapted to integrate and smooth the output of the AND circuit 22 and a comparison circuit 27 are provided after the AND circuit 22, and the output of the comparison circuit 27, namely, a switching signal, is input to a power supply circuit 30. The comparison circuit 27 constantly monitors the output of the AND circuit 22. For example, if the output of the AND circuit 22 changes from a low (L) level to a high (H) level, the comparison circuit 27 outputs a switching signal for turning on the power supply circuit 30. Then, power is supplied from the power supply circuit 30 to the monitor 1, and an image is displayed on a screen (closed switch state).

First, in a state where an operator's finger F does not approach or come in contact with the input key 3, the first counter electrode 13 of the first capacitor 15 is electrically floating, which does not affect the overall circuit. In this case, no phase delay occurs between the clock signal CK input to the first input terminal 22a and the inversion output signal CK-bar of the inverter 23, which is input to the second input terminal 22b. Thus, as shown in FIG. 7A, the output of the AND circuit 22 is maintained at the low (L) level. At this time, a voltage of 0 V is output from the smoothing circuit 26, and the switching signal to be output from the comparison circuit 27 is maintained at the low (L) level. Therefore, the power supply circuit 30 does not operate, and the monitor 1 is in the power-off state (open switch state).

Then, when the operator's finger F approaches or comes in contact with the input key 3, the input key 3 is connected to the ground GND through the body of the operator. At this time, as shown in FIG. 6, a second capacitor 25 is produced between the input key 3 and the ground GND, the second capacitor 25 being formed by the first capacitor 15 and the body of the operator. That is, the second capacitor 25 formed by the body of the operator is connected in series to the first capacitor 15. Although the second capacitor 25 generated by the approach or contact of the operator's finger F is unstable, the second capacitor 25 which is connected in series to the first capacitor 15 serving as a stable fixed capacitor forms a capacitance between the input key 3 and the ground GND. The capacitance between the input key 3 and the ground GND is therefore stable.

If the combined capacitance of the first and second capacitors 15 and 25 is denoted by C, the inversion signal CK-bar input to the second input terminal 22b of the AND circuit 22 has a phase delay which is introduced by a time constant RC determined by the product of the resistance R of the fixed resistor 24 and the combined capacitance C. Thus, as shown in FIG. 7B, due to the phase delay, high-level pulses of a time period t are generated at the output of the AND circuit 22. In this state, a voltage which is not 0 V is output from the smoothing circuit 26, and the switching signal to be output from the comparison circuit 27 is changed to the high (H) level. Therefore, the power supply circuit 30 is turned on, and required power is supplied to the monitor 1 to power on the monitor 1 (closed switch state).

When the operator's finger F approaches or comes in contact with the input key 3 once more, the power supply circuit 30 is turned off, and the monitor 1 is powered off. In this embodiment, therefore, the monitor 1 can be powered on or off only by causing the operator's finger F to approach or come in contact with the input key 3.

In the foregoing embodiment, the substrate 10 is sandwiched between the first and second counter electrodes 13 and 14 to form the first capacitor 15. However, the present invention is not limited to this embodiment. In an embodiment, the pair of counter electrodes 13 and 14 may be placed on either side of a thin flexible resin film sheet (base member) to form the first capacitor 15. In this embodiment, a thin capacitive switch can be achieved.

What is claimed is:

1. A capacitive switch for performing a switch opening and closing operation depending on whether or not a human body approaches or comes in contact with the capacitive switch on the basis of a change in capacitance which is monitored, the capacitive switch comprising:
an electrically conductive input key provided so as to be exposed on a surface of the capacitive switch;
a first capacitor having an end connected to the input key; and
a detection circuit configured to apply a predetermined signal to the first capacitor and to detect an output of the first capacitor to output a switching signal corresponding to the detected output,
wherein the first capacitor comprises a base member and a pair of counter electrodes arranged on either side of the base member so as to face each other with the base member therebetween.

2. The capacitive switch according to claim 1, wherein a connection portion connecting the input key to one of the counter electrodes is provided on a front side of the base member, the connection portion and the one counter electrode being connected via a first coupling line, and the other counter electrode and the detection circuit are connected via a second coupling line on a back side of the base member, and
wherein provided on each of the front and back sides of the base member facing the first coupling line or the second coupling line is a ground electrode arranged so as to surround the first coupling line or the second coupling line.

3. The capacitive switch according to claim 2, wherein the connection portion is surrounded by the ground electrode.

4. The capacitive switch according to claim 1, wherein when a human body approaches or comes in contact with the input key, the first capacitor is grounded via a second capacitor, the second capacitor being formed in association with the approach or contact of the human body.

5. The capacitive switch according to claim 1, wherein the input key is composed of an electrically conductive metal material.

6. The capacitive switch according to claim 1, wherein the input key is composed of an electrically conductive resin material.

7. The capacitive switch according to claim 1, wherein the input key comprises an electrically conductive material laminated on a surface of an insulating resin material.
